(19) United States
(12) Patent Application Publication
(10) Pub. No.: US 2015/0115272 A1
(43) Pub. Date: Apr. 30, 2015

(54) ARRAY SUBSTRATE AND MANUFACTURING METHOD THEREOF, AND DISPLAY DEVICE

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Huiguang Yang, Beijing (CN); Yuqing Yang, Beijing (CN); Tianlei Shi, Beijing (CN); Seung Yik Park, Beijing (CN)

(21) Appl. No.: 14/364,489

(22) PCT Filed: Dec. 9, 2013
(86) PCT No.: PCT/CN2013/088831

§ 371 Date: Jun. 11, 2014

(30) Foreign Application Priority Data
Jul. 10, 2013 (CN) 201310289340.6

(51) Int. Cl. H01L 29/786; H01L 29/417; H01L 27/12

(52) U.S. Cl. CPC H01L 29/78675; H01L 29/78645; H01L 27/124; H01L 27/1237; H01L 29/4175
USPC 257/72; 438/157

(57) ABSTRACT

Embodiments of the disclosure provide an array substrate and a manufacturing method thereof, and a display device. The array substrate includes a thin film transistor formed on a base substrate, a plurality of strip pixel electrodes connected to a drain electrode of the thin film transistor, and a common electrode overlapping with and insulating from the plurality of strip pixel electrodes. The drain electrode has an extension portion, the extension portion extends in an arrangement direction of the plurality of strip pixel electrodes, and each of the strip pixel electrodes is connected to the extension portion.

### TECHNICAL FIELD

Embodiments of the disclosure relate to an array substrate and a manufacturing method thereof, and a display device.

### BACKGROUND

At present, thin film transistor liquid crystal display (TFT-LCD) is developing towards wide viewing angle. Wide viewing angle technologies adapted by the TFT-LCD mainly comprise pixel division technology, optical compensation film technology, in plane switching (IPS) technology, fringe field switching (FFS), advanced super dimension switching (ADS) technology, etc. In the ADS technology, a multi-dimensional electric field is formed with both an electric field generated at edges of slit electrodes in a same plane and an electric field generated between a slit electrode layer and a plate-like electrode layer, so that liquid crystal molecules at all orientations, which are provided directly above the electrodes or between the slit electrodes in a liquid crystal cell, can be rotated, In this way, the operation efficiency of liquid crystal can be enhanced and the light transmittance can be increased. The ADS technology can improve the image quality of the TFT-LCD and has advantages of high resolution, high transmittance, low power consumption, wide viewing angle, high aperture ratio, low chromatic aberration, high response speed, free of push Mura, etc.

The TFT-LCD adopting the ADS technology comprises an array substrate, an opposite substrate and a liquid crystal layer arranged between the array substrate and the opposite substrate. FIG. 1a is a plane schematic diagram illustrating the array substrate according to one technique, and FIG. 1b is a schematic cross section taken along A-A line of FIG. 1a. As shown in FIG. 1a and FIG. 1b, the array substrate comprises a glass substrate 101, a buffer layer 102, a P—Si layer 103, a doped portion 104, a lightly doped portion 105, a gate insulating layer 106, a gate electrode 107, an interlayer insulating layer 108, a drain electrode 109, a source electrode 115, an organic insulating layer 110, a common electrode 111, a passivation layer 112 and a pixel electrode 113. The common electrode 111 is a plate electrode, and the pixel electrode 113 is a slit electrode comprising a plurality of strip electrodes. The plurality of strip electrodes of the pixel electrode 113 are connected with each other by a connection strip 113′. The connection strip 113′ is provided in a same layer as the strip electrodes and is integrally formed with the strip electrodes. The connection strip 113′ and the common electrode 111 have an overlapping region, which causes an interference electric field with a direction different from that of an electric field for controlling liquid crystal deflection. As shown in a region surrounding by the dotted line in FIG. 1a, the interference electric field along a longitudinal direction of the FIG. 1a occurs in this region. In this case, an irregular distribution of liquid crystal molecules is resulted in this region and the transmittance is decreased; and meanwhile, an uneven display easily occurs on the screen of the TFT-LCD when the screen is pressed by external force.

### SUMMARY

According to some embodiments of the disclosure, an array substrate is provided. The array substrate comprises: a thin film transistor formed on a base substrate, a plurality of strip pixel electrodes connected to a drain electrode of the thin film transistor, and a common electrode overlapping with and insulating from the plurality of strip pixel electrodes. The drain electrode has an extension portion, the extension portion extends in an arrangement direction of the plurality of strip pixel electrodes, and each of the strip pixel electrodes is connected to the extension portion.

For example, a projection of the common electrode on the base substrate is not overlapped with a projection of the drain electrode on the base substrate.

For example, the common electrode is a plate electrode and is provided on a side of the drain electrode away from the base substrate, and an insulating layer is provided between the common electrode and the drain electrode; and the plurality of strip pixel electrodes are provided on a side of the common electrode away from the base substrate, and a passivation layer is provided between the plurality of strip pixel electrodes and the common electrode.

For example, the array substrate comprises via holes penetrating through the insulating layer and the passivation layer, and the plurality of strip pixel electrodes are connected to the extension portion of the drain electrode through the via holes.

For example, the array substrate comprises first via holes penetrating through the insulating layer, connection electrodes formed in the first via holes and second via holes penetrating through the passivation layer; and the plurality of strip pixel electrodes are connected to the connection electrodes through the second via holes and the connection electrodes are connected to the extension portion of the drain electrode, so that the plurality of strip pixel electrodes are connected to the extension portion of the drain electrode.

For example, the connection electrodes are made of a conductive material for forming the common electrode.

For example, a thickness of the insulating layer is no less than 1 μm.

For example, the thin film transistor is a low temperature polycrystalline silicon thin film transistor.

According to some embodiments of the disclosure, a manufacturing method of an array substrate is provided. The method comprises: forming a thin film transistor on a base substrate, so that a drain electrode of the thin film transistor has an extension portion and the extension portion extends in an arrangement direction of a plurality of strip pixel electrodes to be formed; and forming a common electrode and the plurality of strip pixel electrodes, each of the strip pixel electrodes being connected to the extension portion.

For example, a projection of the common electrode on the base substrate is not overlapped with a projection of the drain electrode on the base substrate.

For example, the step of forming the common electrode and the plurality of strip pixel electrodes comprises: forming an insulating layer on the base substrate on which the thin film transistor has been formed; forming the common electrode on the insulating layer; forming a passivation layer on the common electrode, and forming via holes penetrating through the passivation layer and the insulating layer; and forming the plurality of strip pixel electrodes so that the plurality of strip pixel electrodes are connected to the extension portion of the drain electrode through the via holes.

For example, the step of forming the common electrode and the plurality of strip pixel electrodes comprises: forming an insulating layer on the base substrate on which the thin film transistor has been formed, and forming first via holes penetrating through the insulating layer; forming the common electrode on the insulating layer, and forming connection electrodes connected to the extension portion of the drain electrode in the first via hole; forming a passivation layer on the common electrode, and forming second via holes penetrating through the passivation layer; and forming the plurality of strip pixel electrodes and connecting the plurality of strip pixel electrodes to the connection electrodes through the second via holes, so that the plurality of strip pixel electrodes are connected to the extension portion of the drain electrode.

For example, the connection electrodes are made of a conductive material for forming the common electrode.

For example, a thickness of the insulating layer is no less than 1 μm.

For example, the thin film transistor is a low temperature polycrystalline silicon thin film transistor.

According to some embodiments of the disclosure, a display device is provided. The display device comprises the array substrate as described above.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1a is a plane schematic diagram illustrating an array substrate according to one technique;

FIG. 1b is a schematic cross section taken along A-A line of the FIG. 1a;

FIG. 2a is a plane schematic diagram illustrating an array substrate according to an embodiment of the disclosure;

FIG. 2b is a schematic cross section taken along A-A line of the FIG. 2a; and

FIG. 2c is a schematic cross section taken along B-B line of the FIG. 2a.

### DESCRIPTION OF THE EMBODIMENTS

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

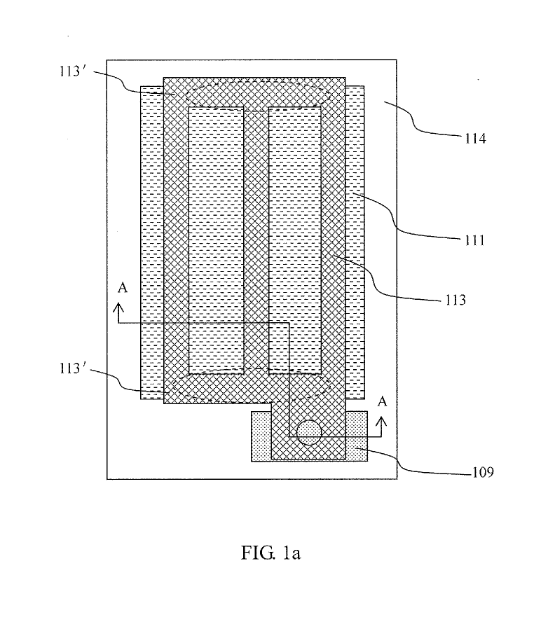

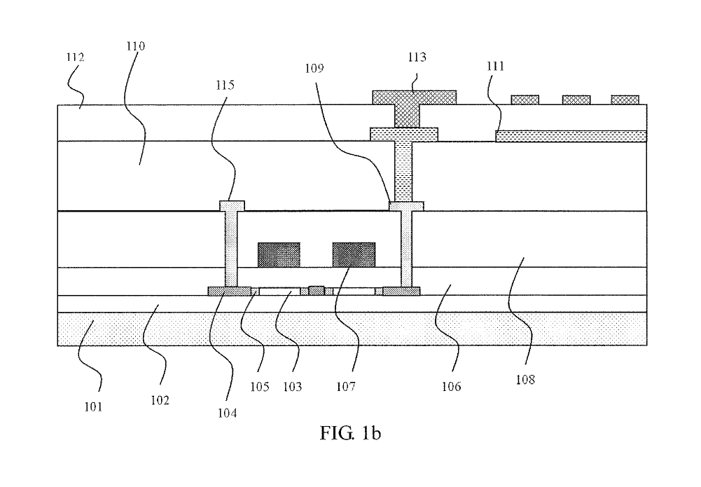

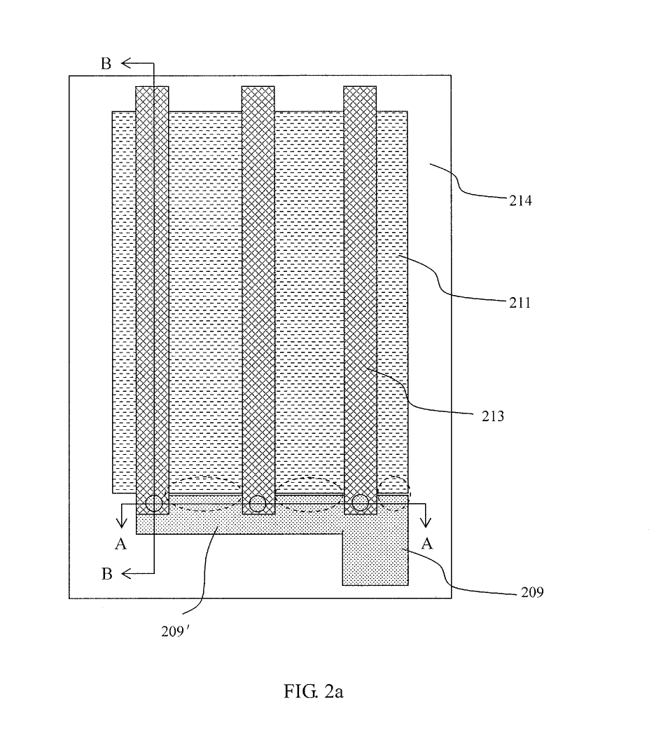

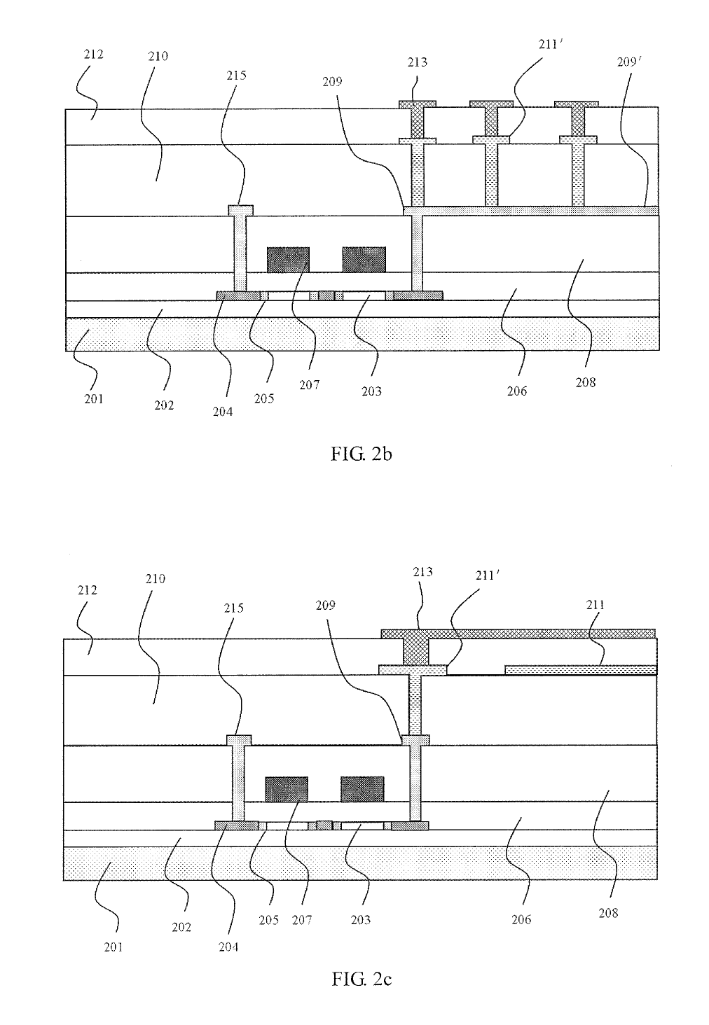

FIG. 2a is a plane schematic diagram illustrating an array substrate according to an embodiment of the disclosure, FIG. 2b is a schematic cross section taken along A-A line of the FIG. 2a, and FIG. 2c is a schematic cross section taken along B-B line of the FIG. 2a. As shown in FIG. 2a, FIG. 2b and FIG. 2c, the array substrate according to the embodiment of the disclosure comprises: a thin film transistor formed on a base substrate 201, a plurality of strip pixel electrodes 213 connected to a drain electrode 209 of the thin film transistor and a common electrode 211 overlapping with and insulating from the plurality of strip pixel electrodes. In the embodiment of the disclosure, the drain electrode 209 has an extension portion 209′, and the extension portion 209′ extends in an arrangement direction of the plurality of strip pixel electrodes 213, and each of the strip pixel electrodes 213 is connected to the extension portion 209′. That is to say, the array substrate according to the embodiment of the disclosure is not provided with the connection strip shown in FIG. 1a. Thus, the problem that the liquid crystal is interfered by the interference electric field between the connection strip and the common electrode can be avoided, the uneven display can be prevented, and the transmittance and the display quality can be improved. To avoid an interference electric field between the common electrode 211 and the drain electrode 209, a projection of the common electrode 211 on the base substrate 201 is not overlapped with a projection of the drain electrode 209 (comprising the extension portion 209′) on the base substrate 201.

For example, the common electrode 211 is a transparent plate electrode and is provided on a side of the drain electrode 209 away from the base substrate 201, and an insulating layer 210 (for example, an organic insulating layer) is provided between the common electrode and the drain electrode 209. As shown in FIG. 2c, the common electrode 211 is provided above the drain electrode 209. The plurality of strip pixel electrodes 213 are provided on a side of the common electrode 211 away from the base substrate 201, and a passivation layer 212 is provided between the plurality of strip pixel electrodes and the common electrode 211. As shown in FIG. 2c, the plurality of strip pixel electrodes 213 are provided above the common electrode 211. The plurality of strip pixel electrodes 213 are connected to the extension portion 209′ of the drain electrode 209 by via holes penetrating through the insulating layer 210 and the passivation layer 212.

For example, material for forming the plurality of strip pixel electrodes 213 directly runs through the via holes so that the plurality of strip pixel electrodes 213 are directly connected to the extension portion 209′ of the drain electrode 209; however, this connection manner is easy to result in a poor connection between the strip pixel electrodes 213 and the extension portion 209′, for example, the material running through the via holes is easy to break.

As shown in FIG. 2b, connection electrodes 211′ are formed by a conductive material for forming the common electrode 211, the plurality of strip pixel electrodes 213 are connected to the connection electrodes 211′, and the connection electrodes 211′ are connected to the extension portion 209′ of the drain electrode 209. In this way, the plurality of strip pixel electrodes 213 are connected to the extension portion 209′ of the drain electrode 209.

The drain electrode 209 has the extension portion 209′. As shown in a region surrounding by the dotted line in the FIG. 2a, an interference electric field may be generated between an edge of the extension portion 209′ and an edge of the common electrode 211, which will result in an irregular arrangement of liquid crystal molecules and a decline in transmittance. Therefore, a thickness of the insulating layer 210 is increased according to the embodiment of the disclosure. For example, the thickness of the insulating layer 210 is no less than 1 μm. The interference electric field is weakened in the case that the thickness of the insulating layer 210 is increased so that the influence on the liquid crystal molecules is negligible.

For example, the thin film transistor is a low temperature polycrystalline silicon thin film transistor. For example, as shown in FIG. 2b, the thin film transistor is of a dual-gate structure, and comprises a P—Si layer 203, a doped portion 204, a lightly doped portion 205, a gate insulating layer 206, a gate electrode 207, an interlayer insulating layer 208, a drain electrode 209 and a source electrode 215 formed on the base substrate 201 (such as, transparent substrate) which has a buffer layer 202.

According to an embodiment of the disclosure, a manufacturing method of an array substrate is provided. For example, the method comprises the following steps.

Step I: forming a thin film transistor on a base substrate, so that a drain electrode of the thin film transistor has an extension portion and the extension portion extends in an arrangement direction of a plurality of strip pixel electrodes to be formed.

The thin film transistor is formed by a normal process except that the drain electrode has the extension portion and the extension portion extends in the arrangement direction of the plurality of strip pixel electrodes to be formed.

Step II: faulting a common electrode and the plurality of strip pixel electrodes, each of the strip pixel electrodes being connected to the extension portion.

For example, the step II is performed in the following manner:

Forming an insulating layer on the base substrate on which the thin film transistor has been formed;

Forming the common electrode on the insulating layer, wherein, for example, a projection of the common electrode on the base substrate is not overlapped with a projection of the drain electrode on the base substrate;

Forming a passivation layer on the common electrode, and forming via holes penetrating through the passivation layer and the insulating layer; and

Forming the plurality of strip pixel electrodes so that the plurality of strip pixel electrodes are connected to the extension portion of the drain electrode through the via holes.

As described above, the via holes through which the plurality of strip electrodes are connected to the extension portion are formed at one time, that is, the strip pixel electrodes are directly connected to the extension portion through the via holes. At this time, the conductive material for forming the strip pixel electrodes continuously runs through two layers (i.e., the passivation layer and the insulating layer), and the conductive material formed in the via holes may have a poor connection with the extension portion especially in a case that the insulating layer is relatively thick (i.e., the via holes are relatively deep). For example, the conductive material formed in the via hole may be uneven, may be not continuous or may be easy to break between the passivation layer and the insulating layer.

To avoid the problems mentioned above, the step II is performed, for example, in the following manner:

Forming the insulating layer on the base substrate on which the thin film transistor has been formed, and forming first via holes penetrating through the insulating layer;

Forming the common electrode on the insulating layer and forming connection electrodes connected to the extension portion of the drain electrode in the first via holes, wherein, for example, the projection of the common electrode on the base substrate is not overlapped with the projection of the drain electrode on the base substrate;

Forming the passivation layer on the common electrode, and forming second via hole penetrating through the passivation layer, wherein, for example, the second via holes are formed to correspond to the first via holes;

Forming the plurality of strip pixel electrodes and connecting the plurality of strip pixel electrodes to the connection electrodes through the second via holes, so that the plurality of strip pixel electrodes are connected to the extension portion of the drain electrode.

For example, the connection electrodes are formed by a conductive material for forming the common electrode. The strip pixel electrodes are connected to the connection electrodes through the second via hole when the plurality of strip pixel electrodes are formed, and the connection electrodes are connected to the extension portion. In this way, the connection reliability between the plurality of strip pixel electrodes and the extension portion of the drain electrode is improved.

For example, a thickness of the insulating layer is no less than 1 μm.

For example, the thin film transistor is a low temperature polycrystalline silicon thin film transistor.

According to an embodiment of the disclosure, a display device is provided. The display device comprises the array substrate as described above. The display device is any product or component having a display function, such as a liquid crystal panel, an electronic paper, a mobile phone, a tablet PC, a TV, a display, a notebook computer, a digital photo frame, a navigator, etc.

The foregoing embodiments merely are exemplary embodiments of the disclosure, and not intended to define the scope of the disclosure, and the scope of the disclosure is determined by the appended claims.

1. An array substrate, comprising: a thin film transistor formed on a base substrate, a plurality of strip pixel electrodes connected to a drain electrode of the thin film transistor, and a common electrode overlapping with and insulating from the plurality of strip pixel electrodes, wherein
the drain electrode has an extension portion, the extension portion extends in an arrangement direction of the plurality of strip pixel electrodes, and each of the strip pixel electrodes is connected to the extension portion.

2. The array substrate according to claim 1, wherein a projection of the common electrode on the base substrate is not overlapped with a projection of the drain electrode on the base substrate.

3. The array substrate according to claim 1, wherein
the common electrode is a plate electrode and is provided on a side of the drain electrode away from the base substrate, and an insulating layer is provided between the common electrode and the drain electrode; and
the plurality of strip pixel electrodes are provided on a side of the common electrode away from the base substrate, and a passivation layer is provided between the plurality of strip pixel electrodes and the common electrode.

4. The array substrate according to claim 3, wherein the array substrate comprises via holes penetrating through the insulating layer and the passivation layer, and the plurality of strip pixel electrodes are connected to the extension portion of the drain electrode through the via holes.

5. The array substrate according to claim 3, wherein the array substrate comprises first via holes penetrating through the insulating layer, connection electrodes formed in the first via holes and second via holes penetrating through the passivation layer; and
the plurality of strip pixel electrodes are connected to the connection electrodes through the second via holes and the connection electrodes are connected to the extension portion of the drain electrode, so that the plurality of strip pixel electrodes are connected to the extension portion of the drain electrode.

6. The array substrate according to claim 5, wherein the connection electrodes are made of a conductive material for forming the common electrode.

7. The array substrate according to claim 3, wherein a thickness of the insulating layer is no less than 1 μm.

8. The array substrate according to claim 1, wherein the thin film transistor is a low temperature polycrystalline silicon thin film transistor.

9. A manufacturing method of an array substrate, comprising:
forming a thin film transistor on a base substrate, so that a drain electrode of the thin film transistor has an extension portion and the extension portion extends in an arrangement direction of a plurality of strip pixel electrodes to be formed; and
forming a common electrode and the plurality of strip pixel electrodes, each of the strip pixel electrodes being connected to the extension portion.

10. The method according to claim 9, wherein a projection of the common electrode on the base substrate is not overlapped with a projection of the drain electrode on the base substrate.

11. The method according to claim 9, wherein the step of forming the common electrode and the plurality of strip pixel electrodes comprises:
forming an insulating layer on the base substrate on which the thin film transistor has been formed;
forming the common electrode on the insulating layer;
forming a passivation layer on the common electrode, and forming via holes penetrating through the passivation layer and the insulating layer; and
forming the plurality of strip pixel electrodes so that the plurality of strip pixel electrodes are connected to the extension portion of the drain electrode through the via holes.

12. The method according to claim 9, wherein the step of forming the common electrode and the plurality of strip pixel electrodes comprises:
forming an insulating layer on the base substrate on which the thin film transistor has been formed, and forming first via holes penetrating through the insulating layer;
forming the common electrode on the insulating layer, and forming connection electrodes connected to the extension portion of the drain electrode in the first via hole;
forming a passivation layer on the common electrode, and forming second via holes penetrating through the passivation layer; and
forming the plurality of strip pixel electrodes and connecting the plurality of strip pixel electrodes to the connection electrodes through the second via holes, so that the plurality of strip pixel electrodes are connected to the extension portion of the drain electrode.

13. The method according to claim 12, wherein the connection electrodes are made of a conductive material for forming the common electrode.

14. The method according to claim 11, wherein a thickness of the insulating layer is no less than 1 μm.

15. The method according to claim 9, wherein the thin film transistor is a low temperature polycrystalline silicon thin film transistor.

16. A display device, comprising the array substrate according to claim 1.

17. The method according to claim 12, wherein a thickness of the insulating layer is no less than 1 μm.
